(19) United States
(12) Patent Application Publication
(10) Pub. No.: US 2024/0178053 A1
(43) Pub. Date: May 30, 2024

(54) INTEGRATED CIRCUIT INCLUDING A PASSIVE COMPONENT IN AN INTERCONNECTION PART, AND CORRESPONDING MANUFACTURING METHOD

(71) Applicants: STMicroelectronics France, Montrouge (FR); STMicroelectronics (Crolles 2) SAS, Crolles (FR)

(72) Inventors: Houssein El Dirani, Draveil (FR); Marouane Mastari, Grenoble (FR); Mohamed Ali Nsibi, Grenoble (FR)

(21) Appl. No.: 18/514,770

(22) Filed: Nov. 20, 2023

(30) Foreign Application Priority Data
Nov. 28, 2022 (FR) 2212439

(51) Int. Cl. H01L 21/762; H01L 23/522

(52) U.S. Cl. CPC H01L 21/76224; H01L 23/5226; H01L 23/5227

(57) ABSTRACT

The integrated circuit includes a semiconductor substrate having a front face including isolation structures that extend vertically into the substrate from the front face as far as a first depth, and an interconnection part comprising metal levels incorporating at least one passive component, above the front face of the substrate. The integrated circuit further includes a dielectric structure that is vertically aligned with the position of the at least one passive component, and that extends vertically into the substrate from the front face as far as a second depth that is greater than the first depth.

### CROSS-REFERENCE TO RELATED APPLICATIONS

This application claims the priority benefit of French Patent Application No. 2212439, filed on Nov. 28, 2022, which application is hereby incorporated by reference herein in its entirety.

### TECHNICAL FIELD

Embodiments and implementations relate to integrated circuits, in particular, integrated circuits including a passive component in an interconnection part, and to methods for manufacturing such integrated circuits.

### BACKGROUND

An interconnection part conventionally includes metal levels, including interconnection tracks and vias vertically connecting the tracks from one level to another. The interconnection part is typically produced above a semiconductor substrate of the integrated circuit. Passive components, such as coils or inductive elements, can typically be made in one of the last metal levels of the interconnection part. They conventionally have a quality factor that depends on the resistivity of the semiconductor substrate facing their positions at the metal level. Due to losses in the substrate, the quality factor of the passive components decreases with a lower substrate resistivity and increases with a higher substrate resistivity. However, an increase in the resistivity of the semiconductor substrate does not conventionally improve the quality factor of the passive components. More specifically, the resistivity of the substrate near the front face strongly decreases due to “thermal budgets” or “annealing,” typically applied in the semiconductor substrate during the manufacture of the integrated circuit.

### SUMMARY

There is thus a need to improve performance, in particular to increase the quality factor, of the passive components of integrated circuits. According to one aspect, the invention proposes in this respect an integrated circuit including a semiconductor substrate having a front face including isolation structures that extend vertically into the substrate from the front face as far as a first depth.

The integrated circuit further comprises an interconnection part comprising metal levels incorporating at least one passive component, above the front face of the substrate.

The integrated circuit further includes a dielectric structure that is vertically aligned with the position of the at least one passive component, and that extends vertically into the substrate from the front face as far as a second depth greater than the first depth.

More specifically, depending on the nominal resistivity (i.e. before annealing for example) of the semiconductor substrate, the resistivity of the substrate advantageously increases as it extends vertically down through the depth, compared to the resistivity at the front face, from the order of magnitude of the depth of conventional isolation structures.

For example, the isolation structures can be shallow isolation trenches (usually referred to as “STI” for “Shallow Trench Isolation”).

These isolation structures, such as shallow isolation trenches, can have a first depth of a few hundred nanometers “nm,” for example 300 nm, or between 100 nm and 500 nm.

A second depth, for example in the order of 500 nm to 1 micrometer “μm,” can allow the resistivity of the semiconductor substrate, compared to the resistivity at the front face, to be increased by a factor of 2 to 10, depending on the nominal resistivity of the semiconductor substrate.

Thus, according to one embodiment, the second depth can be selected such that the resistivity of the semiconductor substrate at the second depth is at least one and a half times greater than the resistivity of the substrate at the first depth, or at least twice as great, or even four to five times as great.

For example, in this respect, the first depth is between 0.1 μm (micrometer) and 0.5 μm (micrometer) and the second depth is between 0.3 μm (micrometer) and 1.5 μm (micrometer).

According to one embodiment, the dielectric structure includes a one-piece block of a dielectric material.

Such a one-piece block can occupy a volume located vertically from the metal level of the passive component of the interconnection part as far as the second depth of the substrate.

According to another embodiment, the dielectric structure includes a one-piece block of a dielectric material, which can occupy a volume located vertically from one of the metal levels of the interconnection part, between the front face of the substrate and the metal level of the passive component, as far as the second depth of the substrate.

For example, the one-piece block of dielectric material can be made of silicon dioxide or a material with a low relative dielectric constant.

Materials with a low relative dielectric constant are usually referred to as “low-k” or “low-κ” (“low-kappa”) materials and are well-known to those skilled in the art.

According to another aspect, the invention further proposes a method for manufacturing an integrated circuit comprising: forming isolation structures in a semiconductor substrate that extend vertically from the front face of the substrate as far as the first depth, forming, above the front face of the substrate, an interconnection part including metal levels incorporating at least one passive component, comprising, prior to the formation of the passive component, forming a dielectric structure that extends vertically into the substrate from the front face as far as a second depth that is greater than the first depth, and aligned vertically with the position of the future passive component.

According to one implementation that can be taken independently, the second depth is selected such that the resistivity of the semiconductor substrate at the second depth is at least one and a half times greater than the resistivity of the substrate at the first depth, or at least twice as great, or even four to five times as great.

For example, the first depth is between 0.1 μm (micrometer) and 0.5 μm (micrometer), and the second depth is between 0.3 μm (micrometer) and 1.5 μm (micrometer).

According to one implementation, the dielectric structure comprises forming a one-piece block of a dielectric material.

This one-piece block can occupy a volume located vertically from the metal level of the passive component of the interconnection part as far as the second depth of the substrate. For example, the formation of the one-piece block comprises an etching step removing the volume from all metal levels of the interconnection part below the metal level of the passive component, and as far as the second depth of the substrate, filling the volume with the dielectric material, and removing an excess of planarized dielectric material from the metal level of the passive component.

According to one implementation, the dielectric structure comprises forming a one-piece block of a dielectric material.

This one-piece block can, in this implementation, occupy a volume located vertically from one of the metal levels of the interconnection part, between the front face of the substrate and the metal level of the passive component, as far as the second depth of the substrate. For example, the formation of the one-piece block comprises etching the volume in all metal levels of the interconnection part below the metal level of the interconnection part, and as far as the second depth of the substrate, filling the volume with the dielectric material, and removing an excess of planarized dielectric material from the metal level of the interconnection part.

For example, the one-piece block of dielectric material is made of silicon dioxide.

### BRIEF DESCRIPTION OF THE DRAWINGS

Other advantages and features of the invention will become apparent upon examining the detailed description of non-limiting embodiments and implementations, and from the accompanying drawings in which:

FIG. 1 diagrammatically shows a sectional view of an integrated circuit after a step of forming the interconnection part;

FIG. 2 shows an etching step for removing a volume from all metal levels of the interconnection part below the metal level of the passive component, and from the pre-metal dielectric layer as well as the shallow isolation trenches all the way into the substrate to the second depth;

FIG. 3 shows a step of forming the damascene-type dielectric structure, including filling the etched volume with a dielectric material, and removing an excess of the planarized dielectric material from the metal level of the passive component;

FIG. 4 shows a device after the step of forming the metal level, including the passive component;

FIG. 5 shows a device after the step of this alternative, wherein the opening of the volume receiving the one-piece block is etched immediately before forming the first metal layer;

FIG. 6 shows a device after the step of filling the opening volume, with the dielectric material and removing an excess of planarized dielectric material from the metal level of the interconnection part;

FIG. 7 shows a device after the step wherein all subsequent metal levels, as far as the metal level including the passive component, have been formed; and

FIG. 8 diagrammatically shows embodiments and implementations thereof.

### DETAILED DESCRIPTION OF EMBODIMENTS

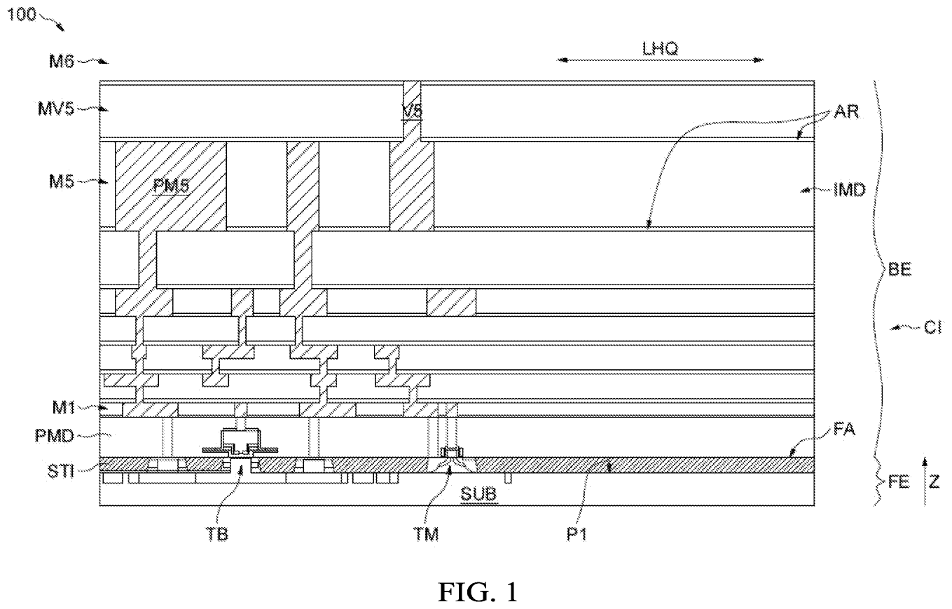

FIGS. 1 to 4 show steps of an example implementation of a method for manufacturing an integrated circuit CI including a passive element LHQ, particularly a high-quality factor inductive element.

FIG. 1 diagrammatically shows a sectional view of the integrated circuit CI after step 100 of forming the interconnection part BE. The interconnection part BE is usually referred to by extension using the acronym “BEOL” for “Back End Of Line”. This acronym “BEOL” refers to the steps involved in manufacturing the interconnection part BE, which includes a network of metal conductor tracks to carry the signals from the integrated circuit CI.

Before the interconnection part BE, a semiconductor part FE of the integrated circuit CI has been formed from a front face FA of a semiconductor substrate SUB. The semiconductor part FE is usually referred to by extension using the acronym “FEOL” for “Front End Of Line”. This acronym “FEOL” refers to the steps for manufacturing the semiconductor part FE, which are carried out in the substrate SUB on the front face FA side and the front face FA.

The semiconductor part FE in particular includes active elements, such as transistors TM of the metal oxide semiconductor “MOS” type or bipolar transistors TB. Moreover, the semiconductor part FE includes isolation structures STI, the formation whereof is usually implemented in the very first steps of manufacturing the integrated circuit CI. The isolation structures STI are typically intended to laterally isolate the active components at the front face FA, and thus delineate “active regions” in the substrate SUB. In this respect, the isolation structures STI extend vertically into the substrate SUB from the front face FA as far as a first depth P1.

For example, the isolation structures STI can be shallow isolation trenches (usually referred to as Shallow Trench Isolation). The formation of these shallow isolation trenches comprises etching open trenches from the front face FA and then filling these open trenches with a dielectric material such as silicon dioxide.

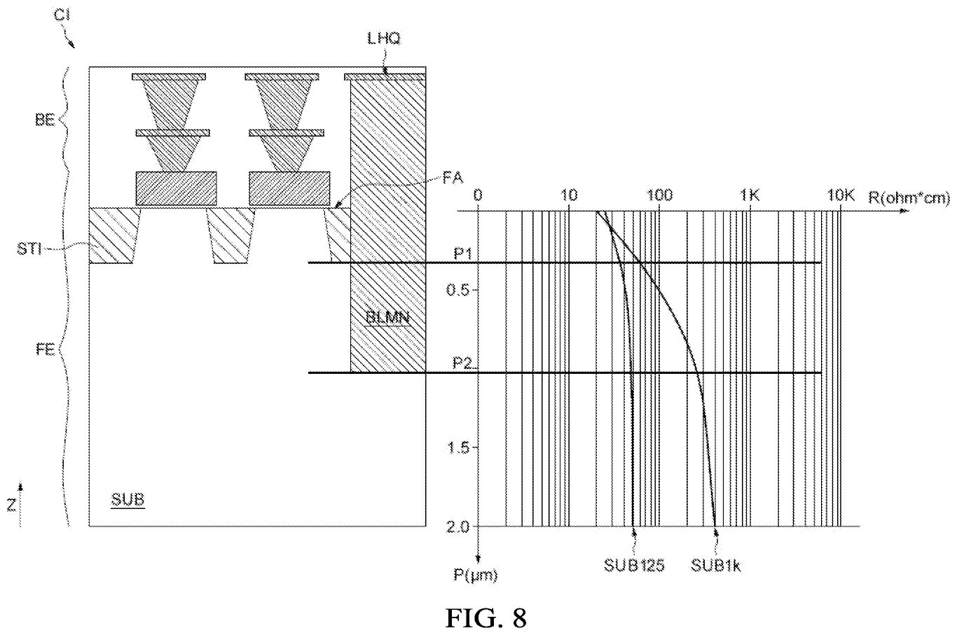

Moreover, the steps of forming the semiconductor part FE typically include annealing steps, requiring “thermal budgets,” comprising high-temperature treatments of varying durations. The various annealing steps tend to lower the resistivity of the substrate SUB at the front face FA, in particular, due to the phenomenon of dopant migration from the substrate SUB. The graph of the reduction in resistivity R according to the depth P of the substrate SUB is shown in FIG. 8, for example.

The steps of forming the semiconductor part FE end with forming a pre-metal oxide layer PMD covering the front face FA and encompassing the elements (for example transistors TM, TB) formed on the front face FA. Vertical metal contacts are provided to connect the elements of the semiconductor part FE electrically. The interconnection part BE is formed above the front face FA of the substrate SUB, on the pre-metal oxide layer PMD thus formed. The pre-metal dielectric layer PMD can be considered to belong to the interconnection part BE.

In the vertical direction Z perpendicular to the front face FA of the substrate SUB, the top of the front face FA is defined such that it is facing away from the substrate SUB, and the bottom is defined such that it is facing from the front face FA towards the substrate SUB.

The interconnection part BE includes metal levels M1, . . . , M5, including metal tracks PM5 located in inter-metal dielectric layers IMD, usually made of silicon oxide. The metal tracks PM5 of each level are typically produced by a damascene process comprising overfilling etched openings in the inter-metal dielectric layer IMD with molten metal. The excess metal above the dielectric layer IMD is removed by planarization, typically by chemical-mechanical polishing “CMP,” stopped by a barrier layer AR, typically made of silicon nitride.

The metal tracks of successive metal levels can be connected by vertical vias V5, made in via levels MV5. The via levels MV5 are a special name for the metal levels of the same nature as those containing metal tracks PM5. In step 100, the structure of the integrated circuit CI is thus conventionally ready for forming the metal level M6 which will contain a passive component LHQ, at a known position.

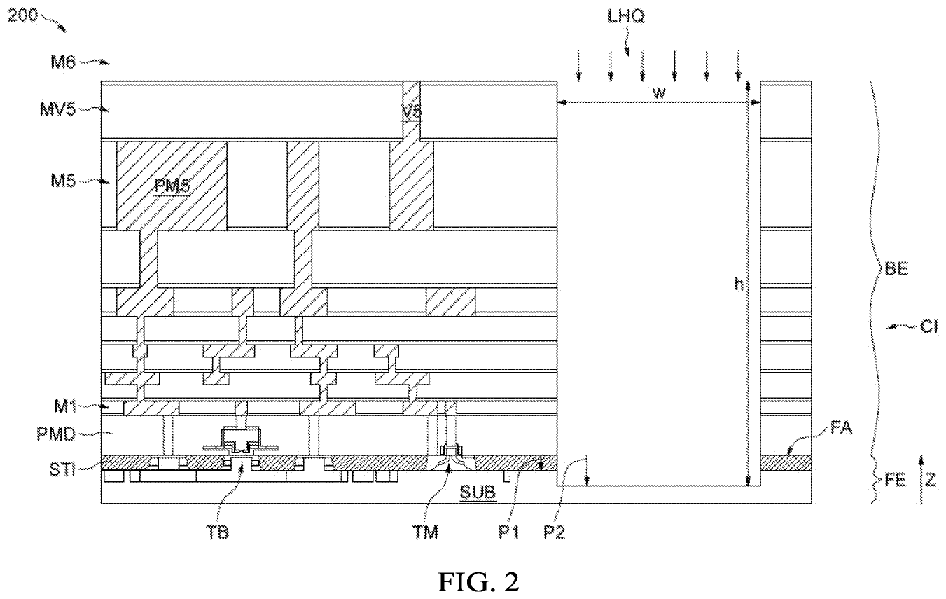

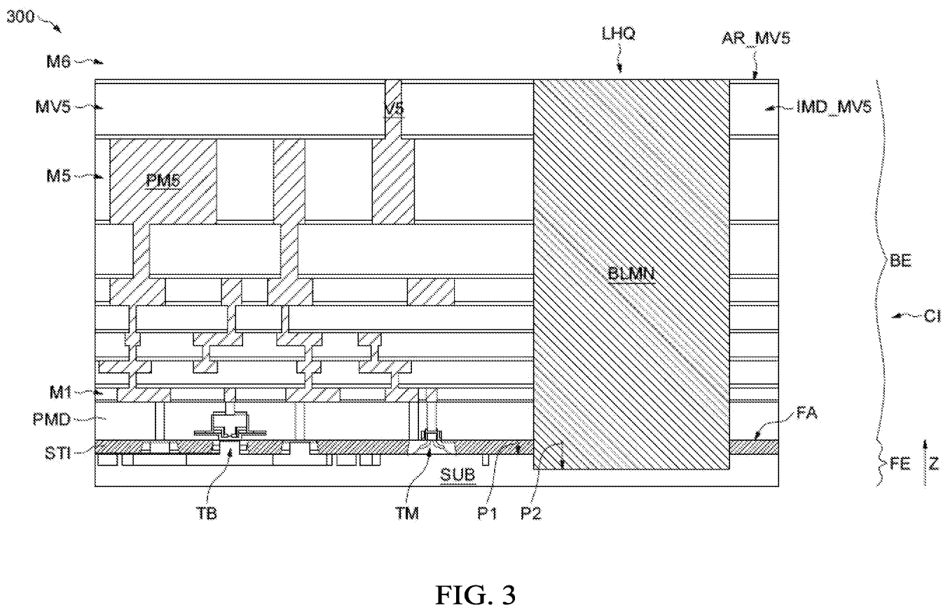

FIGS. 2 and 3 show steps 200, 300 of forming a dielectric structure BLMN, prior to the formation 400 of the metal level M6 which will contain a passive component LHQ. The dielectric structure BLMN extends vertically into the substrate from the front face FA as far as a second depth P2 greater than the first depth P1 and is vertically aligned with the position of the future passive component LHQ. FIG. 2 shows an etching step 200 for removing a volume from all metal levels MV5, M5, . . . , M1 of the interconnection part BE below the metal level M6 of the passive component, and from the pre-metal dielectric layer PMD as well as the shallow isolation trenches STI all the way into the substrate SUB to the second depth P2.

For example, the vertical height h of the etch can be in the order of a few tens of micrometers “μm,” for example between 5 μm and 15 μm. The width w of the etch corresponds to the width of the metal track of the passive component LHQ, for example, a track forming a turn of an inductive element, and can be between 1 μm and 25 μm.

It goes without saying that the values of the height h and width w are not limited, and depend on the selected design of the passive component, including the thickness of the etched metal levels. The etching technique of, for example, the Deep Reactive Ion Etching (DRIE) type, can be selected and adapted so as to be able to etch a given width w to a given depth h.

FIG. 3 shows a step 300 of forming the damascene-type dielectric structure BLMN, including filling the etched volume with a dielectric material, and removing an excess of the planarized dielectric material from the metal level M6 of the passive component.

For example, the etched volume can be filled with the dielectric material BLMN by a High-Density Plasma Deposition (HDPD) technique, such as a chemical vapor deposition of silicon dioxide. The excess dielectric material BLMN above the last inter-metal dielectric layer IMD_MV5 is also removed by planarization of the Chemical-Mechanical Polishing “CMP” type, stopped by the barrier layer AR_MV5 made of silicon nitride.

For example, the dielectric material BLMN is silicon dioxide, or a material with a low relative dielectric constant, usually referred to as “low-k” or “low-κ” (“low-kappa”) materials and are well known to those skilled in the art. “Low-k” materials refer to all dielectric materials that can be used in the microelectronics industry and that have a relative dielectric constant “k” or “κ” (kappa) that is lower than the relative dielectric constant of silicon dioxide. A one-piece block of dielectric material BLMN has thus been formed. This one-piece block of dielectric material BLMN occupies the volume located vertically from the metal level M6 of the passive component LHQ of the interconnection part BE as far as the second depth P2 of the substrate.

More specifically, these damascene-type steps 200-300 result in a formation of the dielectric material in one homogeneous piece, thus constituting a one-piece block BLMN of the dielectric material; in contrast to, for example, the structure of the surrounding interconnection part BE, which includes a succession of layers of silicon oxide IMD and silicon nitride AR (and, moreover, metal tracks and vias).

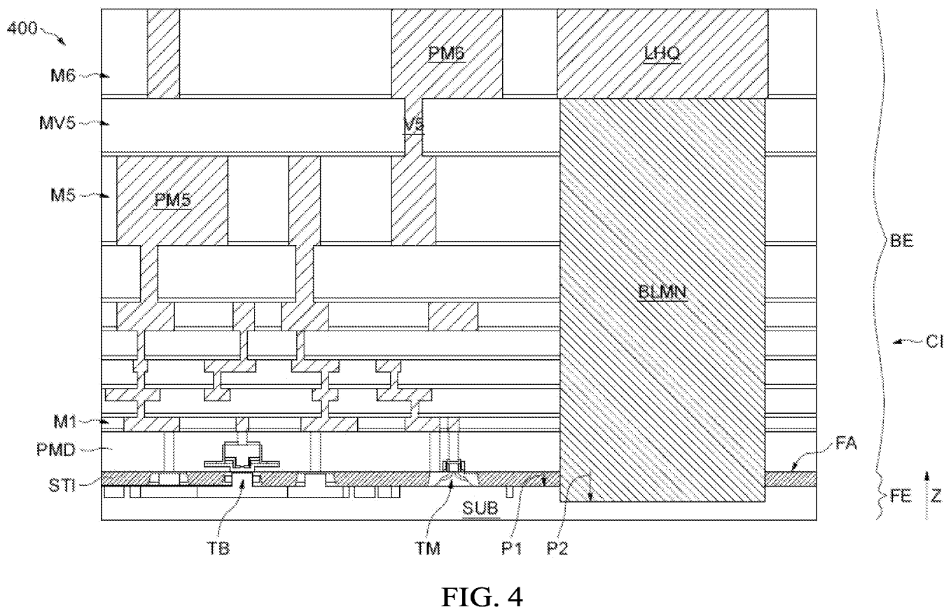

FIG. 4 shows a device after step 400 of forming the metal level M6 including the passive component LHQ. This metal level M6 includes metal tracks PM6 produced by damascene processes that are identical to the process described with reference to FIG. 1 for the formation of the metal tracks PM5.

For example, among the metal tracks PM6, a structure such as a winding of at least one loop, allows the passive component LHQ of the inductive element type to be produced.

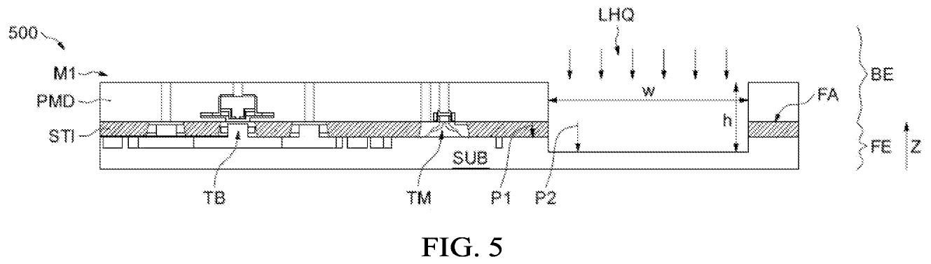

FIGS. 5 to 7 show an alternative example of the manufacturing method described with reference to FIGS. 1 to 4. The elements of the example in FIGS. 5 to 7 that are common to the example in FIGS. 1 to 4 bear the same references and will not all be described again.

FIG. 5 shows a device after step 500 of this alternative, wherein the opening of the volume receiving the one-piece block is etched immediately before forming the first metal layer M1. Thus, the opening is etched into the pre-metal dielectric IMD, into the shallow isolation trenches STI, and into the semiconductor substrate SUB, as far as the second depth P2 (greater than the first depth P1 of the shallow isolation trenches STI).

Alternatively, the opening in step 500 can be etched into all metal levels, from any one of the metal levels of the interconnection part BE located between the front face FA of the substrate SUB and the metal level M6 including the passive component LHQ, as far as the second depth P2 in the substrate SUB.

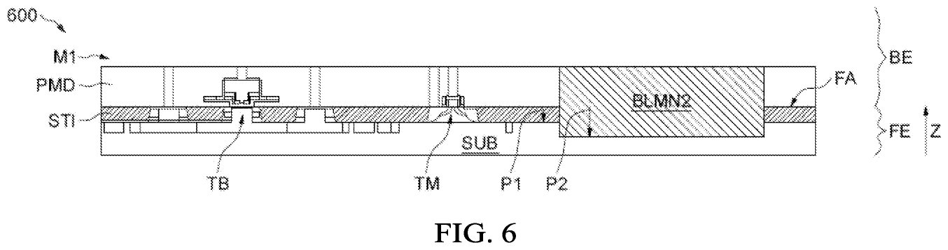

FIG. 6 shows a device after step 600 of filling the opening volume etched in step 500, with the dielectric material BLMN2 and removing an excess of planarized dielectric material from the metal level M1 of the interconnection part. A one-piece block of dielectric material BLMN has thus been formed. This one-piece block of dielectric material BLMN occupies the volume located vertically from one of the metal levels (for example from the first metal level M1) of the interconnection part BE, between the front face FA of the substrate SUB and the metal level M6 of the passive component LHQ, as far as the second depth P2 of the substrate.

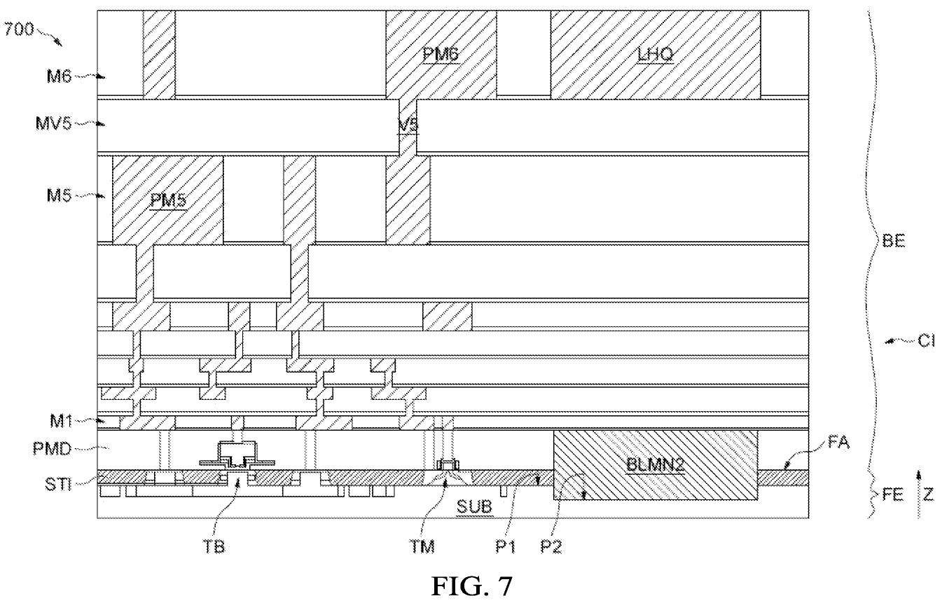

FIG. 7 shows a device after step 700 wherein all subsequent metal levels, as far as the metal level M6 including the passive component LHQ, have been formed. The passive component LHQ is as previously described with reference to FIG. 4. The alternative described with reference to FIGS. 5 to 7 has the particular advantage of etching a smaller height h2, which is thus implemented over a shorter duration.

However, this alternative has the drawback, compared to the method described with reference to FIGS. 1 to 4, that the substrate SUB can undergo annealing steps after the formation of the one-piece dielectric block BLMN, during the formation of the interconnection part BE.

However, the annealing of the interconnection part BE is typically less significant than that of the semiconductor part FE. They also result in a lower reduction of the surface resistivity of the substrate.

In a third alternative, the etching to form the one-piece dielectric block BLMN can take place before the formation of the transistors TB, TM, for example when the shallow isolation trenches STI are being made.

FIG. 8 diagrammatically shows the integrated circuit CI obtained by the methods described hereinabove with reference to FIGS. 1 to 4 and 5 to 7.

The integrated circuit CI in particular includes the dielectric structure BLMN that is vertically aligned with the position of the passive component LHQ, and that extends vertically into the substrate SUB from the front face FA as far as a second depth P2 that is greater than the first depth P1.

FIG. 8 further shows, on the right-hand side, a graph representing the resistivity R of two substrate examples SUB125, SUB1k, in ohms-centimeter “ohm*cm,” as a function of the depth P in the substrate, in micrometers “μm”.

The two substrate examples SUB125 and SUB1k correspond to substrates with nominal resistivities, i.e. summarily, the resistivity at any point of the substrate before the annealing phases, respectively of 125 ohm*cm for a “medium resistivity” substrate SUB125, and 1,000 ohm*cm for a “high resistivity” substrate SUB1k.

In practice, after the annealing phases, the resistivity R of the substrates SUB125, and SUB1k advantageously increases as they extend vertically down through the depth P, compared to the resistivity at the front face FA, from substantially 1 μm, or even 0.5 μm. The axis of the depth P is aligned with the layout of the integrated circuit CI, in particular at the point of origin P=0 μm at the front face FA of the substrate SUB. The first depth P1 of the lateral isolation structures STI can be a few tenths of a micrometer, for example, 0.3 μm, or between 0.1 μm and 0.5 μm.

At the first depth P1, the resistivity of the medium resistivity substrate SUB125 is, for example, 20 to 25 ohm*cm; and the resistivity of the high resistivity substrate SUB1k is, for example, 50 ohm*cm. The second depth P2 is greater than the first depth P1. This second depth P2 is advantageously selected such that the resistivity of the semiconductor substrate SUB at the second depth P2 is at least twice the resistivity of the substrate at the front face FA, for “P=0”. At a second depth P2 of 1 μm, the resistivity of the substrate SUB125 can be, for example, in the order of 40 ohm*cm; and the resistivity of the high resistivity substrate SUB1k is, for example, 250 ohm*cm.

Thus, by etching the silicon of the substrate SUB through the depth, the resistivity of the passive component LHQ, particularly an inductive element, is higher and leakage is lower, such that the quality factor of the passive component has been increased.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. An integrated circuit, comprising:
a semiconductor substrate comprising:
a front face surface,
a plurality of isolation structures, each isolation structure extending vertically into the semiconductor substrate from the front face surface to a first depth of the semiconductor substrate, and
an interconnection part comprising a plurality of metal levels incorporating a passive component; and
a dielectric structure vertically aligned with the passive component, the dielectric structure extending vertically into the semiconductor substrate from the front face surface to a second depth greater than the first depth.

2. The integrated circuit of claim 1, wherein a resistivity of the semiconductor substrate at the first depth is twice a resistivity of the semiconductor substrate at the second depth.

3. The integrated circuit of claim 1, wherein the first depth is between 0.1 micrometers and 0.5 micrometers, inclusive, and wherein the second depth is between 0.3 micrometers and 1.5 micrometers, inclusive.

4. The integrated circuit of claim 1, wherein the dielectric structure comprises a one-piece block of a dielectric material, the one-piece block occupying a volume located vertically from a metal level of the passive component to the second depth of the semiconductor substrate.

5. The integrated circuit of claim 1, wherein the dielectric structure comprises a one-piece block of a dielectric material, the one-piece block occupying a volume located vertically from a metal level of the interconnection part to the second depth of the semiconductor substrate.

6. The integrated circuit of claim 5, wherein the one-piece block comprises silicon dioxide.

7. The integrated circuit of claim 5, wherein the one-piece block has a low relative dielectric constant.

8. A method for manufacturing an integrated circuit, the method comprising:
forming isolation structures in a semiconductor substrate extending vertically from a front face surface of the semiconductor substrate as far as a first depth of the semiconductor substrate;
forming, above a first side of the front face surface of the semiconductor substrate, an interconnection part comprising a plurality of metal levels incorporating a passive component; and
forming, before forming the passive component, a dielectric structure extending vertically into the semiconductor substrate from the front face surface as far as a second depth of the semiconductor substrate is greater than the first depth, the dielectric structure being vertically aligned with the, to be formed, passive component.

9. The method of claim 8, wherein a resistivity of the semiconductor substrate at the first depth is twice a resistivity of the semiconductor substrate at the second depth.

10. The method of claim 8, wherein the first depth is between 0.1 micrometers and 0.5 micrometers, inclusive, and wherein the second depth is between 0.3 micrometers and 1.5 micrometers, inclusive.

11. The method of claim 8, wherein forming the dielectric structure comprises forming a one-piece block of a dielectric material, the one-piece block occupying a volume located vertically from a metal level of the passive component to the second depth of the semiconductor substrate.

12. The method of claim 8, wherein forming the dielectric structure comprises forming a one-piece block of a dielectric material, the one-piece block occupying a volume located vertically from a metal level of the interconnection part to the second depth of the semiconductor substrate.

13. The method of claim 12, wherein the one-piece block comprises silicon dioxide or has a low relative dielectric constant.

14. The method of claim 12, wherein forming the one-piece block comprises:
etching a volume below a metal level of the interconnection part as far as the second depth of the semiconductor substrate;
filling the volume with the dielectric material; and
removing an excess of planarized dielectric material from the metal level of the interconnection part.

15. A device comprising an integrated circuit, the integrated circuit comprising:
a semiconductor substrate comprising:
a front face surface,
a plurality of isolation structures, each isolation structure extending vertically into the semiconductor substrate from the front face surface to a first depth of the semiconductor substrate, and
an interconnection part comprising a plurality of metal levels incorporating a passive component; and
a dielectric structure vertically aligned with the passive component, the dielectric structure extending vertically into the semiconductor substrate from the front face surface to a second depth greater than the first depth.

16. The device of claim 15, wherein a resistivity of the semiconductor substrate at the first depth is twice a resistivity of the semiconductor substrate at the second depth.

17. The device of claim 15, wherein the first depth is between 0.1 micrometers and 0.5 micrometers, inclusive, and wherein the second depth is between 0.3 micrometers and 1.5 micrometers, inclusive.

18. The device of claim 15, wherein the dielectric structure comprises a one-piece block of a dielectric material, the one-piece block occupying a volume located vertically from a metal level of the passive component to the second depth of the semiconductor substrate.

19. The device of claim 15, wherein the dielectric structure comprises a one-piece block of a dielectric material, the one-piece block occupying a volume located vertically from a metal level of the interconnection part to the second depth of the semiconductor substrate.

20. The device of claim 19, wherein the one-piece block comprises silicon dioxide or has a low relative dielectric constant.
